(19) United States
(12) Patent Application Publication
(10) Pub. No.: US 2026/0060120 A1
(43) Pub. Date: Feb. 26, 2026

(54) SEMICONDUCTOR PACKAGE AND SEMICONDUCTOR MODULE INCLUDING THE SAME

(71) Applicant: Samsung Electronics Co., Ltd., Suwon-si (KR)

(72) Inventor: Sohyun Ji, Suwon-si (KR)

(21) Appl. No.: 19/007,931

(22) Filed: Jan. 2, 2025

(30) Foreign Application Priority Data
Aug. 20, 2024 (KR) 10-2024-0111422

(51) Int. Cl. H01L 23/13; H01L 23/00; H01L 23/31; H01L 23/498

(52) U.S. Cl. CPC H01L 23/13; H01L 23/49816; H01L 23/49838; H01L 23/49894; H01L 23/3128; H01L 23/562; H01L 24/11; H01L 24/13; H01L 24/16; H01L 2224/1145; H01L 2224/1146; H01L 2224/13124; H01L 2224/13139; H01L 2224/13144; H01L 2224/13147; H01L 2224/13155; H01L 2224/16227; H01L 2924/1815

(57) ABSTRACT

A semiconductor module may include a package substrate including a first surface and an opposite second surface, a semiconductor chip on the first surface of the package substrate, a plurality of pads on the second surface of the package substrate, and a plurality of solder balls connected to the plurality of pads, respectively, where the package substrate may include a slit in or on the second surface, at least a portion of the slit is disposed between the plurality of solder balls, the slit is spaced apart from the plurality of pads, and a filling layer is in the slit.

### CROSS-REFERENCE TO RELATED APPLICATION

This application claims priority to and the benefit of Korean Patent Application No. 10-2024-0111422, filed in the Korean Intellectual Property Office on Aug. 20, 2024, the entire contents of which is incorporated herein by reference.

### BACKGROUND

The present disclosure relates to a semiconductor package and a semiconductor module including the same.

Due to the recent miniaturization of electronic devices, semiconductor devices are gradually becoming smaller, thinner, and lighter. In addition, semiconductor modules in which a large number of semiconductor devices are mounted are gradually becoming more highly integrated.

A semiconductor package containing a semiconductor chip can be mounted on a module by using the soldering method. In the soldering process, a certain amount of solder material (usually solder paste) is placed on multiple connection terminals and a certain temperature is applied, by which the solder material is shaped into a spherical shape due to surface tension. These spherical-shaped solder materials may be called solder balls.

Meanwhile, board level reliability (BLR) is a concept for evaluating the reliability and durability of semiconductor packages and modules, and BLR tests may include temperature cycling, humidity test, mechanical stress test, electrical stress test, and the like.

A major factor that has a significant impact on semiconductor packages and modules in temperature cycling tests is the difference in coefficient of temperature expansion (CTE) between the semiconductor module and the package. Due to the difference in the CTEs, horizontal forces may be applied at the junctions between modules and packages, which may significantly affect the reliability of semiconductor packages and modules.

Therefore, in order to increase the reliability of semiconductor packages and modules, it is necessary to reduce the stress that may occur in solder balls.

### SUMMARY

Embodiments of the present disclosure may increase the operation reliability of a semiconductor package against temperature change.

In addition, embodiments of the present disclosure may reduce the stress of solder balls due to a difference in coefficients of thermal expansion (CTEs) between a semiconductor package and a module substrate.

In some embodiments, a semiconductor module may include a package substrate including a first surface and an opposite second surface, a semiconductor chip on the first surface of the package substrate, a plurality of pads on the second surface of the package substrate, and a plurality of solder balls connected to the plurality of pads, respectively, where the package substrate may include a slit in or on the second surface, at least a portion of the slit is disposed between the plurality of solder balls, the slit is spaced apart from the plurality of pads, and a filling layer is in the slit.

In some embodiments, a semiconductor package may include a package substrate, a plurality of pads on a first surface of the package substrate, a slit in or on the first surface of the package substrate, at least partially disposed between the plurality of pads, and spaced apart from the plurality of pads, a filling layer within the slit, and a package solder resist layer on the first surface of the package substrate and exposing the plurality of pads and the slit.

In some embodiments, a semiconductor module may include a package substrate including first and second opposite surfaces, a semiconductor chip on the first surface of the package substrate, a sealing member configured to cover the semiconductor chip, a bump on the first surface of the package substrate and connected to the semiconductor chip, a pad on the second surface of the package substrate, and a solder ball connected to the pad, where the package substrate may include a pair of first slits and a pair of second slits in or on the second surface, the first slits extend in a first direction, the second slits extend in a second direction, the first slits and the second slits are spaced apart from the pad, the pad and the solder ball are disposed in a region formed as the pair of first slits and the pair of second slits cross each other, and a filling layer is in the first slits and the second slits.

According to some embodiments, the operation reliability of a semiconductor package against temperature changes may be improved or raised.

In addition, according to some embodiments, the stress occurring at solder balls may be reduced.

### BRIEF DESCRIPTION OF THE DRAWINGS

FIG. 1 is a top plan view of a semiconductor module according to some embodiments.

FIG. 2 is a top plan view showing a portion of a semiconductor module according to some embodiments.

FIG. 3 to FIG. 5 are top plan views showing a portion component of a semiconductor module according to some embodiments.

FIG. 6 is a cross-sectional view taken along line A-A′ of FIG. 2.

FIG. 7 is an enlarged view of the region E of FIG. 6.

FIG. 8 is a cross-sectional view taken along line B-B′ of FIG. 2.

FIG. 9 is a cross-sectional view of a semiconductor module according to some embodiments.

FIG. 10 and FIG. 11 are top plan views of a slit according to some embodiments.

### DETAILED DESCRIPTION

The present disclosure will be described more fully hereinafter with reference to the accompanying drawings, in which example embodiments of the disclosure are illustrated. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for better understanding and ease of description, the thicknesses of some layers and areas may be exaggerated.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising”, will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

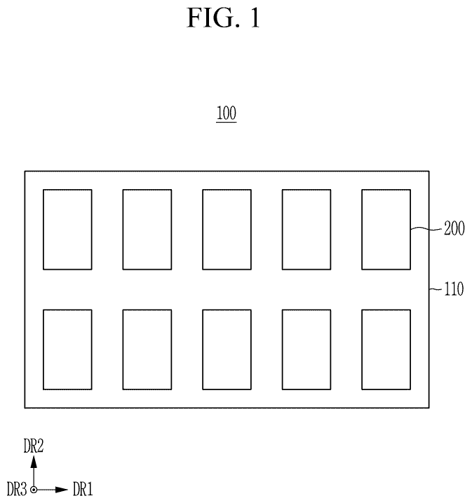

FIG. 1 is a top plan view of a semiconductor module according to some embodiments.

Referring to FIG. 1, a semiconductor module 100 according to some embodiments may include a module substrate 110 and a semiconductor package 200 disposed on the module substrate 110.

The module substrate 110 may include a first surface and a second surface facing or opposite the first surface. The first surface and the second surface may face or be opposite each other in a third direction DR3. The semiconductor package 200 may be disposed on the first surface of the module substrate 110. As an example, the module substrate 110 may be a printed circuit board (PCB).

One or more semiconductor packages 200 may be disposed on the module substrate 110. The semiconductor packages 200 disposed on the module substrate 110 may be disposed to have a uniform or non-uniform interval, and as needed, may be disposed in various ways.

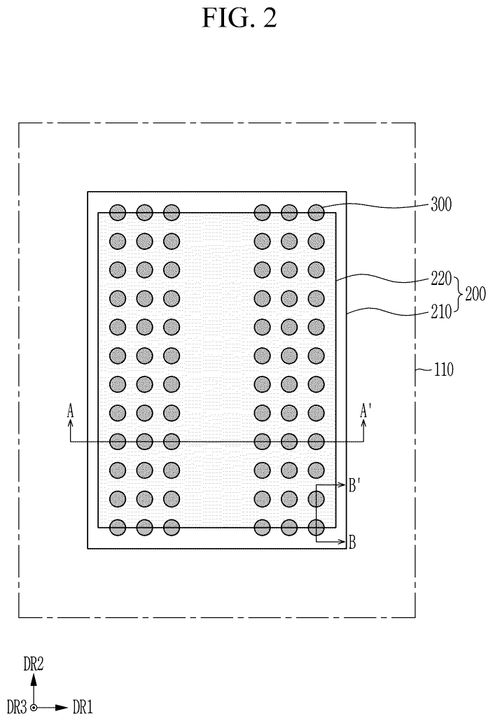

FIG. 2 is a top plan view showing a portion of the semiconductor module according to some embodiments.

Referring to FIG. 2, the semiconductor package 200 may be disposed on the module substrate 110. The semiconductor package 200 may include a package substrate 210 and a semiconductor chip 220.

The package substrate 210 may include the first surface and the second surface facing or opposite the first surface. The first surface and the second surface may face or be opposite each other in the third direction DR3. The semiconductor chip 220 may be disposed on a first surface of the package substrate 210. As an example, the package substrate 210 may be a printed circuit board (PCB). As an example, the first surface of the package substrate 210 where the semiconductor chip 220 is disposed may be an upper surface.

The semiconductor package 200 and the module substrate 110 may be connected to each other through one or more solder balls 300. The solder ball 300 may be located between the module substrate 110 and the semiconductor package 200. The solder ball 300 may be disposed on a side toward the second surface of the package substrate 210. As an example, the side toward the second surface of the package substrate 210 where the solder ball 300 is disposed may be a side toward or on a lower surface of the package substrate 210. In addition, the solder ball 300 may be disposed on a side toward the first surface of the module substrate 110. As an example, the side toward the first surface of the module substrate 110 where the solder ball 300 is disposed may be a side toward or on an upper surface of the module substrate 110.

A plurality of solder balls 300 may be disposed according to a predetermined rule, but it is not limited thereto, and may be disposed irregularly, or according to various rules that may be changeable as needed.

The coefficient of thermal expansion of the semiconductor package 200 may be calculated in consideration of the coefficients of thermal expansion (CTE) of the package substrate 210, the semiconductor chip 220, and other components included in the semiconductor package. The semiconductor package 200 may be connected to the module substrate 110 through the solder ball 300. The coefficient of thermal expansion of the semiconductor package 200 may be different from a coefficient of thermal expansion of the module substrate 110. As an example, the coefficient of thermal expansion of the semiconductor package 200 may be smaller than the coefficient of thermal expansion of the module substrate 110, but is not limited thereto.

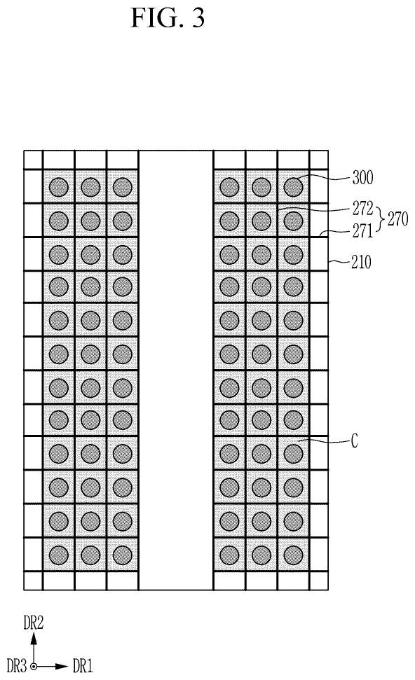

FIG. 3 to FIG. 5 are top plan views showing a portion component of the semiconductor module according to some embodiments.

Referring to FIG. 3, a slit 270 may be disposed on the second surface of the package substrate 210 according to some embodiments. The slit 270 may include a first slit 271 and a second slit 272. As an example, the second surface of the package substrate 210 may mean the lower surface of the package substrate 210.

The slit 270 may mean a gap formed in the package substrate 210. One or more slits 270 may be disposed. That is, the first slit 271 and the second slit 272 may be disposed in a quantity of one or more.

The first slit 271 may be an elongated slit extending in a first direction DR1 in a plan view. The second slit 272 may be an elongated slit extending in a second direction DR2 crossing the first direction DR1 in a plan view. The second direction DR2 may be a direction vertically crossing the first direction DR1. As an example, the first slit 271 may extend in a horizontal direction, and the second slit 272 may extend in a vertical direction in a plan view.

For example, the first direction DR1 and second direction DR2 may be perpendicular to one another. According to some embodiments, the first direction DR1 and second direction DR2 may form a plane which is parallel to a plane formed by the second surface of the package substrate 210.

The first slit 271 may extend to a first side edge of the package substrate 210 along the first direction DR1 in a plan view, and the second slit 272 may extend to a second side edge of the package substrate 210 along the second direction DR2 in a plan view.

As an example, the first slit 271 may extend to a left-side edge, a right-side edge, or both horizontal (left-side and right-side) edges of the package substrate 210, in a plan view. In addition, as an example, the second slit 272 may extend to an upper-side edge, a lower-side edge, or both (upper-side and lower-side) vertical edges of the package substrate 210, in a plan view.

The solder ball 300 may be disposed on a side toward the second surface of the package substrate 210. In addition, one or more solder balls 300 may be disposed on a side toward the second surface of the package substrate 210. The slit 270 may be disposed between the plurality of solder balls 300. In other words, the first slit 271 and the second slit 272 may be disposed between the plurality of solder balls 300. The first slit 271 may be located between the solder balls 300 adjacent one another in the second direction DR2, and the second slit 272 may be located between the solder balls 300 adjacent one another in the first direction DR1. The first slit 271 and the second slit 272 may be disposed to cross each other. As an example, the first slit 271 and the second slit 272 may perpendicularly cross each other, in a plan view.

A plurality of first slits 271 may be disposed to be spaced apart to have a regular interval, and may be disposed to be spaced apart to have different intervals, as needed. A plurality of second slits 272 may be disposed to be spaced apart to have a regular interval, and may be disposed to be spaced apart to have different intervals, as needed.

The plurality of solder balls 300 may be disposed in a lattice form or array form or grid form, in a plan view. As the plurality of solder balls 300 are disposed in the lattice form, a lattice region C may be formed. The lattice region C formed by the plurality of solder balls 300 may be a concept including a region where the solder balls 300 are disposed and its peripheral area. The number of the lattice region C formed in the second surface of the package substrate 210 may be one, and may be two or more. In addition, FIG. 3 illustrates that two lattice regions C of a rectangular shape are disposed, but it is not limited thereto, and as needed, the number and the shape of the lattice region C may be changed in various ways.

The slit 270 may also be disposed on the edge of the lattice region C. That is, the first slit 271 and the second slit 272 may also be disposed on the edge of the lattice region C. In other words, the slits 270, 271, 272 may be disposed between the plurality of solder balls 300 and an edge of the lattice region C or an edge of the package substrate 210. The solder ball 300 may be disposed to be surrounded by the first slit 271 and the second slit 272. As an example, the solder ball 300 may be disposed between a pair of first slits 271 and a pair of second slits 272, and in other words, may be disposed in a region formed as the pair of first slits 271 and the pair of second slits 272 cross each other.

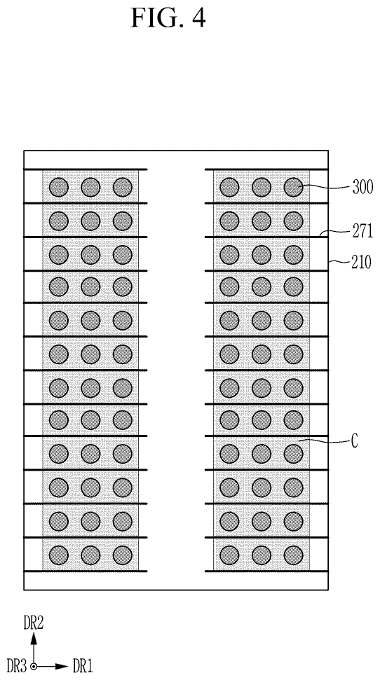

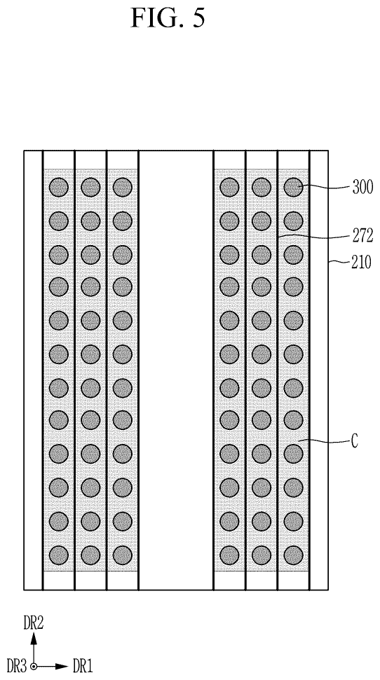

A slit of only one direction among the slit 270 in various directions may be disposed on the second surface of the package substrate 210. As an example, as shown in FIG. 4, only the first slit 271 extending the first direction DR1 may be disposed on the second surface of the package substrate 210. In addition, as an example, as shown in FIG. 5, only the second slit 272 extending the second direction DR2 may be disposed on the second surface of the package substrate 210.

As the slit 270 is formed on the package substrate 210, according to the difference of coefficients of thermal expansion between the semiconductor package 200 and the module substrate 110, the stress that may occur to be applied to the solder ball 300 may be decreased.

As an example, since a degree of freedom of deformation of the package substrate 210 may be raised by the slit 270 formed in the package substrate 210, the stress applied to the solder ball 300 may decrease.

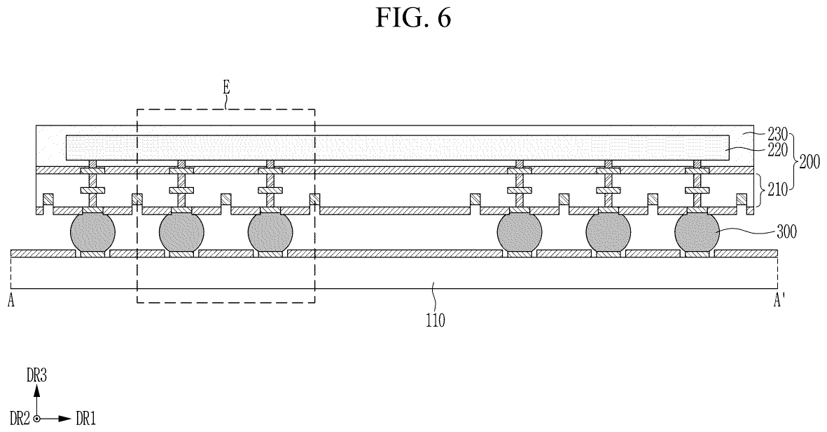

FIG. 6 is a cross-sectional view taken along line A-A′ of FIG. 2.

In more detail, FIG. 6 is a cross-sectional view of the semiconductor package 200 shown in FIG. 2 taken along line A-A′ when viewed in the second direction DR2.

Referring to FIG. 6, one or more the solder ball 300 may be disposed on the module substrate 110, and the semiconductor package 200 may be connected to the module substrate 110 through the solder ball 300. The package substrate 210 may be disposed on the solder ball 300 and the module substrate 110. In addition, the semiconductor chip 220 may be disposed on the package substrate 210, and the semiconductor chip 220 may be covered or surrounded by a sealing member 230, on the package substrate 210.

The module substrate 110 may serve to integrate a plurality of semiconductor chips 220 or other components.

Meanwhile, the semiconductor package 200 may include a connection member 240, a first package solder resist layer 252, a first package solder resist opening, a first package pad 254, a second package solder resist layer 262, a second package solder resist opening 262_O, and a second package pad 264, which are described below.

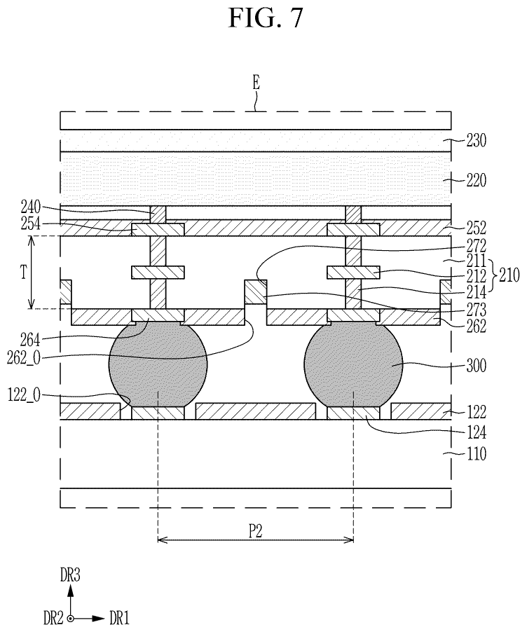

FIG. 7 is an enlarged view of the region E of FIG. 6.

In more detail, FIG. 7 is an enlarged view of the region E of FIG. 6 when the semiconductor module 100 is viewed in the second direction DR2.

The module substrate 110 may include a thermosetting resin such as an epoxy resin, a thermoplastic resin such as a polyimide, or a photosensitive resin, but is not limited thereto, and may be altered to various insulation resins.

A module solder resist layer 122 may be disposed on the module substrate 110. In addition, a module pad 124 may be disposed on the module substrate 110. The module pad 124 may include a conductive material. As an example, the module pad 124 may include copper (Cu), aluminum (Al), silver (Ag), tin (Sn), gold (Au), nickel (Ni), lead (Pb), titanium (Ti), or an alloy thereof, but is not limited thereto.

The module solder resist layer 122 may include a module solder resist layer opening 122_O exposing at least a portion of the module substrate 110 and/or the module pad 124.

The module solder resist layer 122 may be disposed to cover or surround at least a portion of the module pad 124, and may be disposed to be spaced apart from the module pad 124 by a preset interval.

The solder ball 300 may be disposed on the module pad 124, and the module pad 124 may be connected to the solder ball 300, electrically and physically.

The solder ball 300 may electrically connect the package substrate 210 to an external component. The external component may include, for example, a main board or motherboard of an electronic device. The solder ball 300 may have a ball shape.

The solder ball 300 may include, for example, an alloy of tin (Sn), lead (Pb), silver (Ag), copper (Cu), or the like, but is not limited thereto.

The solder ball 300 may be connected to the second package pad 264 disposed on the second surface of the package substrate 210.

When viewed in the second direction DR2, an interval or spacing between a pair of solder balls 300 may be a second pitch P2. The second pitch P2 may mean a center-to-center interval between the pair of solder balls 300.

A lower surface of the module solder resist layer 122 may be located at substantially the same vertical level as a lower surface of the module pad 124 (e.g., lower surfaces of the module solder resist layer 122 and the module pad 124 may be coplanar), but is not limited thereto.

The package substrate 210 may include an insulation layer 211, a wire layer 212, and a via 214. The package substrate 210 may have a specific thickness T. The insulation layer 211 may include a thermosetting resin such as an epoxy resin, a thermoplastic resin such as polyimide, or a photosensitive resin, but is not limited thereto, and may be altered to various insulation resins.

The wire layer 212 may include a conductive material. As an example, the wire layer 212 may include copper (Cu), aluminum (Al), silver (Ag), tin (Sn), gold (Au), nickel (Ni), lead (Pb), titanium (Ti), or an alloy thereof, but is not limited thereto.

The wire layer 212 may perform various functions depending on the design of that layer. For example, the wire layer 212 may include a ground (GND) pattern, a power (PWR) pattern, and/or a signal (S) pattern. Here, the signal (S) pattern may include various signals, for example, data signals pattern, excluding the ground (GND) pattern and the power (PWR) pattern.

The wire layer 212 may be disposed in a quantity of one or more, and as an example, a plurality of wire layers 212 may be located at different levels in the third direction DR3.

The via 214 may electrically connect between the wire layers 212 located at different levels. The via 214 may include a conductive material. The via 214 may be completely filled with, for example, a conductive material, but is not limited thereto. As another example, the via 214 may be formed with a conductive material along the wall of the via hole.

Although FIG. 6 to FIG. 9 illustrate, for convenience, that a width (the width along the first direction DR1 and/or the second direction DR2) of the via 214 is uniform, but the width of the via 214 may become thinner or thicker toward the third direction DR3. For example, the width may become narrower from a layer where the etching starts to a layer where the etching is finished in the process of etching the via holes.

At least one via 214 may have a shape that penetrates the insulation layer 211 located between the wire layers 212 adjacent one another in the third direction DR3. The insulation layer 211 may surround at least one wire layer 212 and the at least one via 214. The insulation layer 211 may surround an upper surface, a lower surface, and a side surface of the at least one wire layer 212. The insulation layer 211 may surround a side surface of the at least one via 214.

A second package solder resist layer 262 may be disposed on the second surface of the package substrate 210. In addition, the second package pad 264 may be disposed on the second surface of the package substrate 210. The second package solder resist layer 262 may include a second package solder resist layer opening 262_O exposing the second surface of the package substrate 210 and/or at least a portion of the second package pad 264.

As an example, the second surface of the package substrate 210 where the second package solder resist layer 262 and the second package pad 264 are disposed may be the lower surface of the package substrate 210.

The second package solder resist layer 262 may be disposed to cover or surround at least a portion of the second package pad 264, and may be disposed to be spaced apart from the second package pad 264 by a preset interval.

The second package pad 264 may include a conductive material, for example the same as the module pad 124. The second package pad 264 may be disposed on the solder ball 300. The second package pad 264 may be connected to the solder ball 300, electrically and physically. As an example, the second package pad 264 may be disposed to face the module pad 124 disposed on the module substrate 110, interposing the solder ball 300.

An upper surface of the second package solder resist layer 262 may be located at substantially the same level as an upper surface of the second package pad 264 (e.g., upper surfaces of the second package solder resist layer 262 and the second package pad 264 may be coplanar), but is not limited thereto.

In addition, the second slit 272 may be disposed on the package substrate 210. The second slit 272 may mean a lengthy or elongated gap or groove or trench extending in the second direction DR2. The second slit 272 may be disposed between the plurality of solder balls 300.

In addition, the second slit 272 may be disposed to be spaced apart from the second package pad 264. In other words, a side surface or upper and lower surfaces of the second slit 272 may be disposed so as not to contact a side surface or upper and lower surfaces of the second package pad 264. In addition, the second slit 272 may be disposed to be also spaced apart from the solder ball 300.

The second package solder resist layer opening 262_O may be disposed at a position corresponding to the second slit 272 on the second surface of the package substrate 210.

Therefore, on the second surface of the package substrate 210, the second slit 272 may not be covered with the second package solder resist layer 262, and may be exposed to the outside.

A filling layer 273 may be disposed within the second slit 272. The filling layer 273 may include at least one among epoxy resin, acrylate, phenol resin, silicone resin, and polyimide. In addition, as an example, the filling layer 273 may include a die attach film (DAF). However, a composition of the filling layer 273 may not be limited to the materials listed above.

As an example, the filling layer 273 may be placed within the slit 270 through a dispenser, which is a device that outputs a material, but is not limited thereto.

The filling layer 273 may fill the second slit 272 as much as a volume of 50% or more and 100% or less. For example, a height of the filling layer 273 may be 50% or more and 100% or less of a depth of the second slit 272.

The filling layer 273 may be disposed within the slit 270, to prevent damage or destruction of the package substrate 210. As an example, the filling layer 273 may serve to absorb the stress applied to the package substrate 210.

As an example, the filling layer 273 may have adhesiveness, and may have variable, stretchable, or flexible properties, in order to raise the degree of freedom of deformation of the package substrate 210.

A first package solder resist layer 252 may be disposed on the first surface of the package substrate 210. In addition, the first package pad 254 may be disposed on the first surface of the package substrate 210. The second package solder resist layer 262 may include the second package solder resist layer opening 262_O exposing at least a portion of the second surface of the package substrate 210 and/or the second package pad 264.

As an example, the first surface of the package substrate 210 where the first package solder resist layer 252 and the first package pad 254 are disposed may be an upper surface of the package substrate 210.

The first package solder resist layer 252 may be disposed to cover or surround at least a portion of the first package pad 254, and may be disposed to be spaced apart by a preset interval from the first package pad 254.

A lower surface of the first package solder resist layer 252 may be located at substantially the same level as a lower surface of the first package pad 254 (e.g., lower surfaces of the first package solder resist layer 252 and the first package pad 254 may be coplanar), but is not limited thereto.

The first package pad 254 may include a conductive material, for example the same as the module pad 124. The first package pad 254 may be connected to the semiconductor chip 220 through the connection member 240.

The connection member 240 may mean, as an example, bump, but is not limited thereto. The connection member 240 may include a conductive material, for example, a metal such as copper (Cu), aluminum (Al), gold (Au), silver (Ag) nickel (Ni), or the like. As an example, the connection member 240 may be formed by a plating or sputtering process.

The connection member 240 may have, for example, a pillar shape. A planar shape of the connection member 240 may be, for example, a circular, elliptical, rectangular, polygonal, or hexagonal shape, but is not limited thereto, and may be changed in various ways.

The connection member 240 may be disposed to contact an upper surface of the first package pad 254.

The semiconductor chip 220 may be sealed by the sealing member 230, on the first surface of the package substrate 210. The sealing member 230 may cover an upper surface and a side surface of the semiconductor chip 220. The sealing member 230 may surround a side surface of the connection member 240, between a lower surface of the semiconductor chip 220 and the first surface of the package substrate.

The sealing member 230 may include, for example, an Epoxy Molding Compound (EMC), but is not limited thereto.

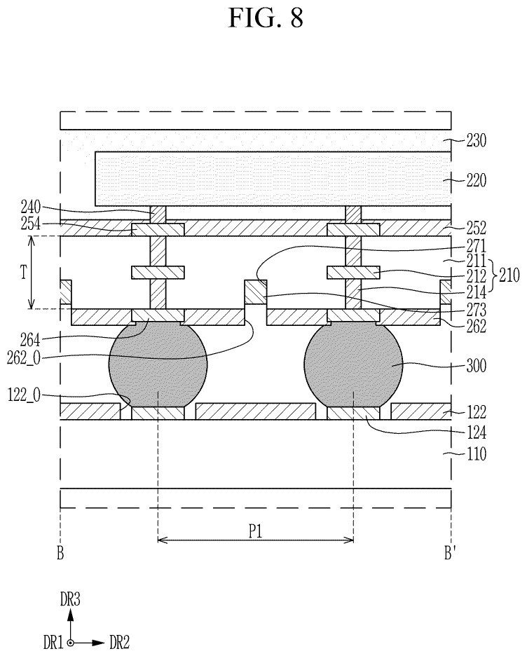

FIG. 8 is a cross-sectional view taken along line B-B′ of FIG. 2.

In more detail, FIG. 8 is a cross-sectional view of the semiconductor package 200 shown in FIG. 2 taken along line B-B′ when viewed in the first direction DR1.

When viewed in the first direction DR1, an interval or spacing between the pair of solder balls 300 may be a first pitch P1. The first pitch P1 may mean a center-to-center interval between the pair of solder balls 300.

In addition, the first slit 271 may be disposed on the package substrate 210. The first slit 271 may mean a lengthy or elongated gap or groove or trench extending in the first direction DR1. The first slit 271 may be disposed between the plurality of solder balls 300. In addition, the first slit 271 may be disposed to be spaced apart from the first package pad 254. In other words, a side surface or upper and lower surfaces of the first slit 271 may be disposed so as not to contact a side surface or upper and lower surfaces of the first package pad 254. In addition, the first slit 271 may be disposed to be also spaced apart from the solder ball 300 and/or the second package pad 264.

The second package solder resist layer opening 262_O may be disposed at a position corresponding to the first slit 271 on the second surface of the package substrate 210. Therefore, on the second surface of the package substrate 210, the first slit 271 may not be covered with the second package solder resist layer 262, and may be exposed to the outside.

The filling layer 273 may be disposed within the first slit 271. The filling layer 273 may include at least one among epoxy resin, acrylate, phenol resin, silicone resin, and polyimide. In addition, as an example, the filling layer 273 may include a die attach film (DAF). However, the composition of the filling layer 273 may not be limited to the materials listed above.

The filling layer 273 may fill the first slit 271 as much as a volume of 50% or more and 100% or less. For example, the height of the filling layer 273 may be 50% or more and 100% or less of the depth of the first slit 271.

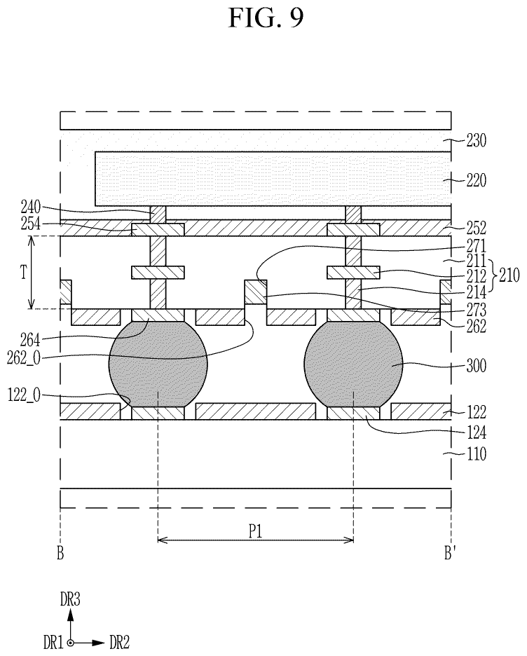

FIG. 9 is a cross-sectional view showing a semiconductor module according to some embodiments.

When FIG. 8 and FIG. 9 are compared, in the semiconductor module 100 according to some embodiments, the second package solder resist layer 262 may be disposed to cover or surround at least a portion of the second package pad 264, and may be disposed to be spaced apart from the second package pad 264 by a preset interval.

That is, the semiconductor module 100 according to some embodiments may be applied with all of the solder-mask defined (SMD) method and the non-solder-mask defined (NSMD) method.

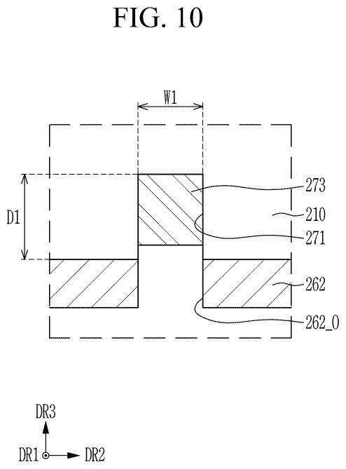

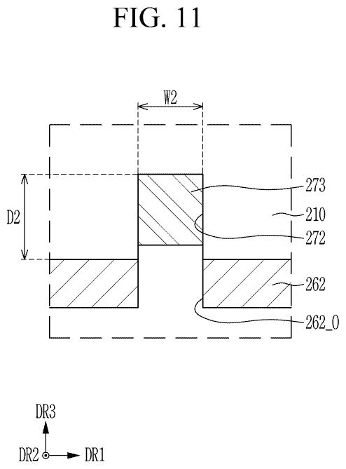

FIG. 10 and FIG. 11 are top plan views of a slit according to some embodiments.

Referring to FIG. 10, the first slit 271 may be disposed on the second surface of the package substrate 210. The first slit 271 may extend along the first direction DR1. The first slit 271 may be exposed by the second package solder resist layer opening 262_O.

A depth D1 of the first slit 271 may be ½ or less of the thickness T of the package substrate 210. As an example, the depth D1 of the first slit 271 may be one of 1/100 or more, 1/50 or more, 1/25 or more, 1/10 or more, ⅕ or more, ¼ or more, and ⅓ or more of the thickness T of the package substrate 210, but is not limited thereto.

In addition, as an example, the depth D1 of the first slit 271 may be one of 50 μm, 60 μm, 70 μm, 80 μm, 90 μm, 100 μm, 110 μm, 120 μm, 130 μm, 140 μm, 150 μm, 160 μm, 170 μm, 180 μm, 190 μm, 200 μm, 210 μm, 220 μm, 230 μm, 240 μm, 250 μm, 260 μm, 270 μm, 280 μm, 290 μm, and 300 μm. As an example, the depth D1 of the first slit 271 may be 100 μm or more and 200 μm or less.

A width W1 of the first slit 271 may be ⅓ or less of an interval P1 between the pair of solder balls 300 viewed in the first direction DR1. As an example, the width W1 of the first slit 271 may be one of 1/100 or more, 1/50 or more, 1/25 or more, 1/10 or more, ⅕ or more, and ¼ or more of the interval P1 between the pair of solder balls 300 viewed in the first direction DR1, but is not limited thereto.

As an example, the width W1 of the first slit 271 may be one of 0.1 mm, 0.2 mm, 0.3 mm, 0.4 mm, 0.5 mm, 0.6 mm, 0.7 mm, 0.8 mm, 0.9 mm, 1 mm, 1.5 mm, 2 mm, 2.5 mm, 3 mm, 3.5 mm, 4 mm, 4.5 mm, and 5 mm. In addition, as an example, the width W1 of the first slit 271 may be 0.5 mm or more and 1 mm or less.

The filling layer 273 may be disposed within the first slit 271. The filling layer 273 may fill 50% or more and 100% or less of the volume of the first slit 271. In addition, the height of the filling layer 273 may be 50% or more and 100% or less of the depth D1 of the first slit 271.

Referring to FIG. 11, the second slit 272 may be disposed on the second surface of the package substrate 210. The second slit 272 may extend along the second direction DR2. The second slit 272 may be exposed by the second package solder resist layer opening 262_O.

A depth D2 of the second slit 272 may be ½ or less of the thickness T of the package substrate 210. As an example, the depth D2 of the second slit 272 may be one of 1/100 or more, 1/50 or more, 1/25 or more, 1/10 or more, ⅕ or more, ¼ or more, and ⅓ or more of the thickness T of the package substrate 210, but is not limited thereto.

As an example, the depth D2 of the second slit 272 may be one of 50 μm, 60 μm, 70 μm, 80 μm, 90 μm, 100 μm, 110 μm, 120 μm, 130 μm, 140 μm, 150 μm, 160 μm, 170 μm, 180 μm, 190 μm, 200 μm, 210 μm, 220 μm, 230 μm, 240 μm, 250 μm, 260 μm, 270 μm, 280 μm, 290 μm, and 300 μm. As an example, the depth D2 of the second slit 272 may be 100 μm or more and 200μm or less.

A width W2 of the second slit 272 may be ⅓ or less of an interval P2 between the pair of solder balls 300 viewed in the second direction DR2. As an example, the width W2 of the second slit 272 may be one of 1/100 or more, 1/50 or more, 1/25 or more, 1/10 or more, ⅕ or more, ¼ or more of the interval P2 between the pair of solder balls 300 viewed in the second direction DR2, but is not limited thereto.

As an example, the width W2 of the second slit 272 may be one of 0.1 mm, 0.2 mm, 0.3 mm, 0.4 mm, 0.5 mm, 0.6 mm, 0.7 mm, 0.8 mm, 0.9 mm, 1 mm, 1.5 mm, 2 mm, 2.5 mm, 3 mm, 3.5 mm, 4 mm, 4.5 mm, and 5 mm. In addition, as an example, the width W2 of the second slit 272 may be 0.5 mm or more and 1 mm or less.

The filling layer 273 may be disposed within the second slit 272. The filling layer 273 may fill 50% or more and 100% or less of the volume of the second slit 272. In addition, the height of the filling layer 273 may be 50% or more and 100% or less of the depth D2 of the second slit 272.

The depth D1 and the width W1 of the first slit 271 may be the same as the depth D2 and the width W2 of the second slit 272, but is not limited thereto. That is, the depth D1 and the width W1 of the first slit 271 may be different from the depth D2 and the width W2 of the second slit 272.

While this disclosure has been described in connection with what is presently considered to be practical embodiments, it is to be understood that the disclosure is not limited to the disclosed example embodiments. On the contrary, it is intended to cover various modifications and equivalent arrangements included within the spirit and scope of the appended claims.

What is claimed is:

1. A semiconductor module, comprising:
a package substrate comprising a first surface and an opposite second surface;
a semiconductor chip on the first surface of the package substrate;
a plurality of pads on the second surface of the package substrate; and
a plurality of solder balls connected to the plurality of pads, respectively,
wherein the package substrate comprises a slit in or on the second surface, at least a portion of the slit is disposed between the plurality of solder balls, the slit is spaced apart from the plurality of pads, and a filling layer is in the slit.

2. The semiconductor module of claim 1, wherein the slit comprises at least one first slit and at least one second slit, and the first slit extends in a first direction, and the second slit extends in a second direction that crosses the first direction.

3. The semiconductor module of claim 2, wherein the first slit extends to a first side edge of the package substrate, and the second slit extends to a second side edge of the package substrate.

4. The semiconductor module of claim 1, wherein a depth of the slit is ½ or less of a thickness of the package substrate.

5. The semiconductor module of claim 1, wherein a width of the slit is ⅓ or less of an interval between adjacent solder balls among the plurality of solder balls.

6. The semiconductor module of claim 1, wherein the filling layer comprises at least one among epoxy resin, acrylate, phenol resin, silicone resin, and polyimide.

7. The semiconductor module of claim 6, wherein a thickness or height of the filling layer is 50% or more and 100% or less of a depth of the slit.

8. The semiconductor module of claim 1, wherein a depth of the slit is 100 μm or more and 200 μm or less.

9. The semiconductor module of claim 1, wherein a width of the slit is 0.5 mm or more and 1 mm or less.

10. The semiconductor module of claim 1, wherein the plurality of solder balls is disposed in a lattice form, forming a lattice region.

11. The semiconductor module of claim 10, wherein the slit is additionally disposed between the lattice region and a side edge of the package substrate.

12. A semiconductor package, comprising:
a package substrate;
a plurality of pads on a first surface of the package substrate;
a slit in or on the first surface of the package substrate, at least partially disposed between the plurality of pads, and spaced apart from the plurality of pads;
a filling layer within the slit; and
a package solder resist layer on the first surface of the package substrate and exposing the plurality of pads and the slit.

13. The semiconductor package of claim 12, wherein the slit comprises at least one first slit and at least one second slit, the first slit extends in a first direction, and the second slit extends in a second direction that crosses or intersects the first direction.

14. The semiconductor package of claim 13, wherein the first slit extends to a first side edge of the package substrate, and the second slit extends to a second side edge of the package substrate that is perpendicular to the first side edge of the package substrate.

15. The semiconductor package of claim 12, wherein the plurality of pads is disposed in a lattice form in a lattice region.

16. The semiconductor package of claim 15, wherein the slit is additionally disposed between the lattice region and a side edge of the package substrate.

17. The semiconductor package of claim 12, wherein the filling layer comprises at least one among epoxy resin, acrylate, phenol resin, silicone resin, and polyimide.

18. The semiconductor package of claim 17, wherein a thickness of the filling layer is 50% or more and 100% or less of a depth of the slit.

19. A semiconductor module, comprising:
a package substrate comprising first and second opposite surfaces;
a semiconductor chip on the first surface of the package substrate;
a sealing member configured to cover the semiconductor chip;
a bump on the first surface of the package substrate and connected to the semiconductor chip;
a pad on the second surface of the package substrate; and
a solder ball connected to the pad,
wherein the package substrate comprises a pair of first slits and a pair of second slits in or on the second surface, the first slits extend in a first direction, the second slits extend in a second direction, the first slits and the second slits are spaced apart from the pad, the pad and the solder ball are disposed in a region formed as the pair of first slits and the pair of second slits cross each other, and a filling layer is in the first slits and the second slits.

20. The semiconductor module of claim 19, wherein the filling layer comprises at least one among epoxy resin, acrylate, phenol resin, silicone resin, and polyimide.
